(19) United States
(12) Patent Application Publication
(10) Pub. No.: US 2008/0150023 A1
(43) Pub. Date: Jun. 26, 2008

(54) Semiconductor memory and manufacturing method thereof

(75) Inventor: Mika Nishisaka, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/000,878

(22) Filed: Dec. 18, 2007

(30) Foreign Application Priority Data
Dec. 20, 2006 (JP) 2006-342240

(51) Int. Cl. H01L 29/786; H01L 21/336

(52) U.S. Cl. 257/344; 438/163; 257/E21.411; 257/E29.266

(57) ABSTRACT

In the semiconductor memory of the present invention, the impurity concentration of the high-doped region in the drain region is lower than that of the high-doped region in the source region. The drain region having a lower impurity concentration suppresses the GIDL leakage. The source region having a higher impurity concentration suppresses the leakage of stored charge to between the body and the source region. As a result, the semiconductor memory is enabled to have a memory cell with excellent data holding characteristic.

This application is based upon and claims the benefit of priority from Japanese patent application No. 2006-342240, filed on Dec. 20, 2006, the disclosure of which is incorporated herein in its entirety by reference.

### FIELD OF THE INVENTION

The present invention relates to a semiconductor memory, and in particular to a semiconductor memory composed of single-transistor-cell type memory cells.

### DESCRIPTION OF THE RELATED ART

In general, each memory cell in a dynamic random access memory (hereafter, referred to as DRAM) is composed of a single MOSFET and a capacitor. As a submicron technology of DRAM memory, a trench capacitor structure or a stacked capacitor structure is adopted, and thus the memory capacity of the DRAMs has been increased. On the other hand, in order to improve the submicron technology, several other types of semiconductor memories have been proposed in which each one-bit memory cell is composed of a single MOSFET without using a capacitor. Such a semiconductor memory composed of a single MOSFET is called 1T-DRAM.

One of these proposals relates to a semiconductor memory in which a channel body of an MOSFET fabricated on a silicon on insulator (hereafter, referred to as SOI) wafer (hereafter, referred to as SOI-MOSFET) is used as a memory node. The SOI-MOSFET has a floating body effect causing occurrence of excessive charge in the channel body, and the SOI-MOSFET is a memory utilizing this floating body effect. In this type of memory, holes are stored in the channel body of the MOSFET, and data is defined as “1,” or “0” according to the amount of the stored holes. Such proposal is disclosed, for example, in S. Okhonin, et. al., “A Capacitor-Less 1T-DRAM Cell” IEEE Electron Device Letters, vol. 23, (2002) pp. 85-87 (Non-Patent Document 1). This memory cell, using no capacitor, is called zero-capacitor RAM (referred to as ZRAM in abbreviation).

In a 1T-DRAM employing an SOI-MOSFET, the amount of stored holes is decreased as the elapse of time. Therefore, the 1T-DRAM also requires a refresh operation like an ordinary DRAM. Two approaches are conceivable to improve the refresh characteristic. A first one is to increase the amount of generated holes and a second one is to enhance the hole holding characteristic. A method has been proposed as the first approach in which the amount of impact ionization is increased by setting high the impurity concentration of an extension region of a drain region side (Japanese Patent Publication Tokkai 2003-031696 (Patent Document 1)). According to this method, however, the electric field in the vicinity of the gate electrode and the drain region is increased, resulting in increase of gate induced drain leakage (also referred to as junction leak current, and hereafter referred to as GIDL leakage for brevity). It has also been reported that the GIDL leakage induces a problem of deterioration of the refresh characteristic (Y Minami et. al., A Floating Body Cell fully Compatible with 90 nm CMOS Technology for 128 Mb SOI DRAM, IEDM2005. FIG. 9, FIG. 10 (Non-Patent Document 2)).

Japanese Patent Publication Tokkai 2003-124476 (Patent Document 2) discloses a method in which the leak current is suppressed by using a first semiconductor for forming a channel while using a second semiconductor different from the first one for forming a part or the entire of a source-drain region.

Japanese Patent Publication Tokuhyo 2000-517483 (Patent Document 3) discloses a method in which injection of hot carriers into a gate insulating film is suppressed by forming an IGFET source-drain region asymmetrically.

However, none of these prior art documents discloses or suggests the problems of the present invention or techniques to solve the problems.

As described above, the IT-DRAM utilizing an SOI-MOSFET still has problems to solve. The GIDL leakage must be decreased and the refresh characteristic must be improved.

### SUMMARY OF THE INVENTION

In view of the problems as described above, the present invention aims to provide a semiconductor memory capable of improving the refresh characteristic, and a manufacturing method of such a semiconductor memory.

A semiconductor memory according to this invention is composed of single-transistor-cell type memory cells. A memory cell transistor formed in a semiconductor region on an insulating film includes a drain region, a source region, and a gate electrode. Each of the drain region and the source region has a lightly-doped region and a high-doped region. The high-doped regions of the drain region and source region are asymmetrical, having different impurity concentrations from each other.

In a manufacturing method of a semiconductor memory according to this invention, the semiconductor memory is composed of single-transistor-cell type memory cells. The manufacturing method comprises the steps of isolating an element region in a semiconductor region on an insulating film by surrounding the element region with an element isolation insulating film and forming a gate electrode on the semiconductor region with a gate insulating film interposed therebetween. The manufacturing method further comprises the steps of implanting an impurity in lightly-doped regions of a drain region and a source region in the semiconductor region, implanting an impurity only in a high-doped region of the source region, and further implanting an impurity in the high-doped regions of the drain region and the source region.

A semiconductor memory according to the present invention is characterized in that a source region and a drain region of an SOI-MOSFET are asymmetrical to each other in terms of the impurity concentration. Specifically, the impurity concentration of a high-doped region in the drain region is set lower than the impurity concentration of a high-doped region in the source region. It is made possible to relieve the electric field and to suppress the GIDL leakage by setting lower the impurity concentration of the drain region. Further, the source region having a higher impurity concentration increases the potential barrier between the body region and the source region, whereby the leakage of stored charge to between the body and the source region can be suppressed. This effectively improves the data holding characteristic. The present invention thus is capable of providing a semiconductor memory with excellent refresh characteristic and a manufacturing method of such a semiconductor memory.

### BRIEF DESCRIPTION OF THE DRAWINGS

FIG. 1 is a cross-sectional view showing a memory cell structure of a semiconductor memory according to a first exemplary embodiment of the present invention;

FIG. 2 shows an equivalent circuit of a memory cell array according to the present invention;

FIG. 3 is a cross-sectional view for explaining an element isolation process and a gate electrode formation process in a manufacturing method of the semiconductor memory according to the first exemplary embodiment;

FIG. 4 is a cross-sectional view for explaining a first ion implantation process of a manufacturing method of the semiconductor memory according to the first exemplary embodiment;

FIG. 5 is a cross-sectional view for explaining a second ion implantation process of a manufacturing method of the semiconductor memory according to the first exemplary embodiment;

FIG. 6 is a cross-sectional view for explaining a third ion implantation process of a manufacturing method of the semiconductor memory according to the first exemplary embodiment;

FIG. 7A and FIG. 7B are cross-sectional views for explaining a “1” writing operation (FIG. 7A) and a “0” writing operation (FIG. 7B) in a memory cell according to the present invention; and

FIG. 8 is a cross-sectional view showing a memory cell structure in a semiconductor memory according to a second exemplary embodiment of the present invention.

### DESCRIPTION OF THE PREFERRED EMBODIMENTS

Exemplary embodiments of a semiconductor memory according to the present invention will be described with reference to the accompanying drawings.

### First Exemplary Embodiment

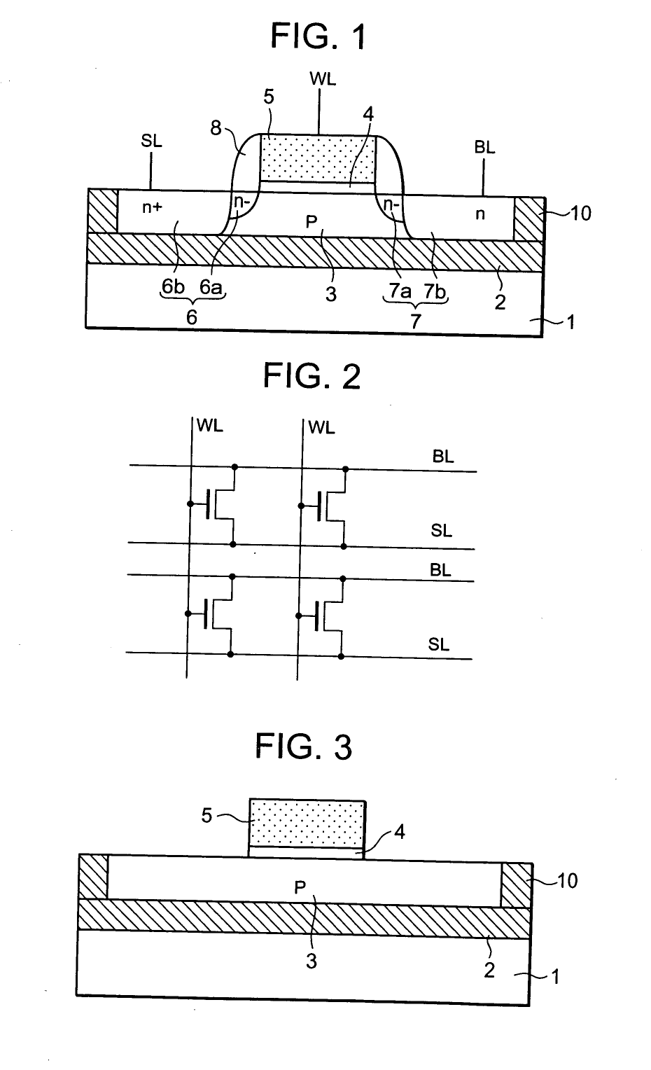

Referring to FIGS. 1 to 7, a semiconductor memory according to a first exemplary embodiment of the present invention will be described. FIG. 1 is a cross-sectional view showing a memory cell structure in the semiconductor memory of the first exemplary embodiment.

The memory cell shown in FIG. 1 is composed of an n-channel MOSFET. A silicon substrate 1 and a P-type silicon layer 3 together form an SOI substrate while being separated by an insulating film 2 such as a silicon oxide film. The SOI substrate may be fabricated by implanting ions in the silicon substrate to bury an oxide film or by bonding silicon substrates. An element region is isolated by means of an element isolation insulating film 10. The P-type silicon layer 3 is caused to serve as an electrically floating body, and a gate electrode 5 is formed thereon with a gate insulating film 4 interposed therebetween.

Further, an n-type source region 6 and an n-type drain region 7 are formed in self-alignment with the gate electrode 5.

The source region 6 and the drain region 7 are each composed of a lightly-doped region (n⁻-type layer) 6a, 7a formed to have a shallow depth in contact with the channel region, and a high-doped region 6b (n⁺-type layer), 7b (n-type layer) formed to have a depth reaching the insulating film 2. The SOI-MOSFET has a lightly doped drain (LDD) structure having a lightly-doped region (n⁻-type layer) formed to have a shallow depth to serve as an extension region, and a high-doped region (n⁺-type layer, n-type layer) formed to have a great depth. The high-doped region (n⁺-type layer) 6b in the source region 6 has an impurity concentration ND1 while the high-doped region (n-type layer) 7b in the drain region 7 has an impurity concentration ND2 such that ND1 is higher than ND2. In other words, the source region 6 and the drain region 7 are asymmetrical to each other in terms of the impurity concentration.

With reference to FIG. 2 together with FIG. 1, the memory cell composed of a single transistor has the gate electrode 5 connected to a word line WL, the drain region 7 connected to a bit line BL, and the source region 6 connected to a source line SL. A plurality of such memory cells are arranged in a matrix, and connected to the word lines WL, the bit lines BL, and the source line SL in common, as shown in FIG. 2, to form a cell array. When the cell array is formed in this manner, the P-type silicon layer 3 in each cell is isolated to be in the floating state.

A manufacturing method of the memory cell according to the first exemplary embodiment of the invention will be described with reference to FIGS. 3 to 6. FIG. 3 is a cross-sectional view of an MOSFET using an SOI substrate, on which an element isolation process and a gate electrode formation process have been performed. A P-type silicon layer 3 is formed on an insulating film 2 on a silicon substrate 1. An element region is isolated by an element isolation insulating film 10. A gate insulating film 4 is formed on the P-type silicon layer 3, and a gate electrode 5 is further formed on the gate insulating film 4.

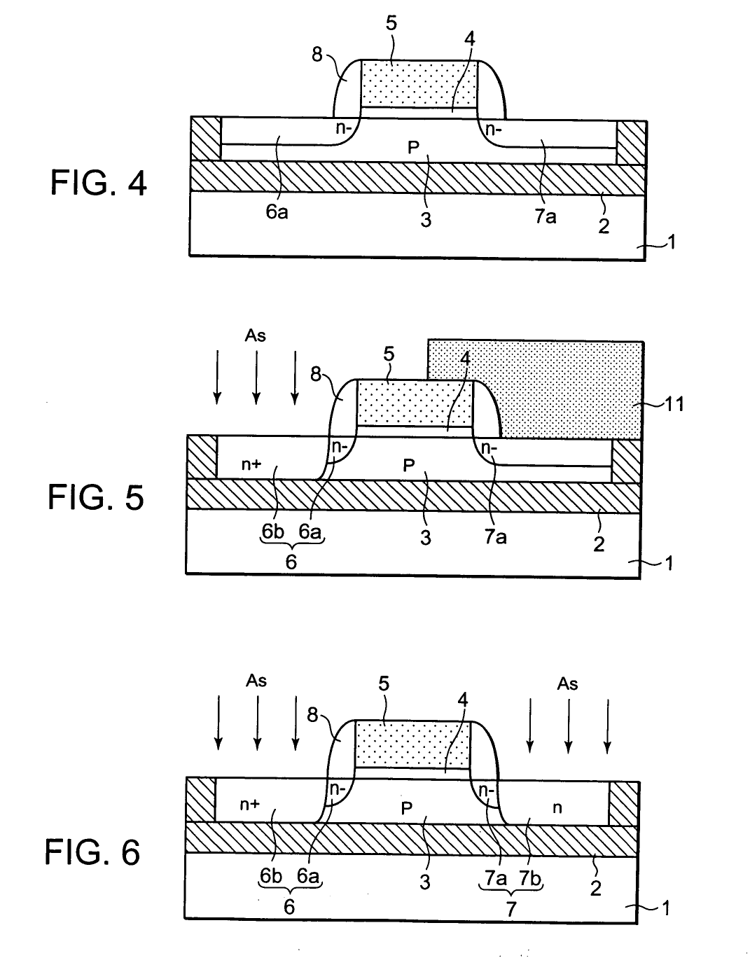

As shown in FIG. 4, a first ion implantation process is performed on the P-type silicon layer 3 to form lightly-doped regions (ne-type layer) 6a and 7a with a shallow implantation depth so that these regions function as extension regions. Further, a side-wall insulating film 8 is formed to surround the gate electrode 5.

Subsequently, as shown in FIG. 5, the drain region region of the transistor is covered with a resist 11, and an impurity (arsenic As) implanted in the source region. The impurity is implanted only in the source region so that the impurity concentration differs between the source region and the drain region.

After removing the resist, arsenic As is implanted into the whole surface of the transistor for forming a source region and a drain region as shown in FIG. 6. As a result, a high-doped region (n⁺-type layer) 6b is formed as the source region and a high-doped region (n-type layer) 7b is formed as the drain region. The impurity concentration ND1 of the high-doped region 6b in the source region is higher than the impurity concentration ND2 of the high-doped region 7b in the drain region. However, it is obvious that the impurity concentration ND2 of the high-doped region 7b in the drain region is higher than the impurity concentration of the lightly-doped region.

When performing the arsenic (As) implantation processes shown in FIGS. 5 and 6, conditions for the implantation and conditions for heat treatment to be performed after the implantation are set such that the implantation depth is deep enough so that high-doped regions 6b and 7b reach the insulating film 2. As shown in FIG. 5, the drain region side is covered with the resist 11 so that only the source region side is doped with ions, whereby the drain region and the source region are caused to have different impurity concentrations, that is, they are made asymmetrical in terms of the impurity concentration.

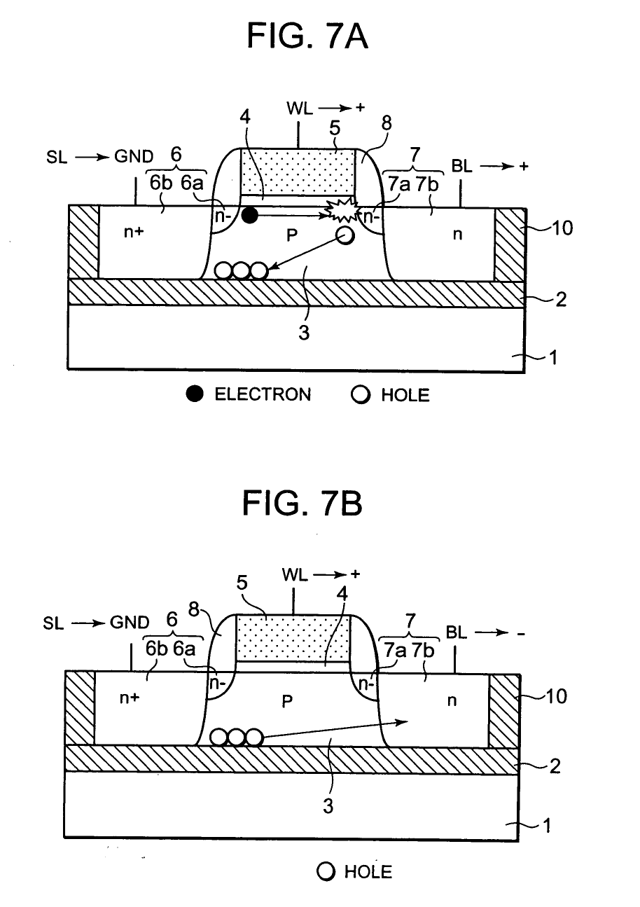

Description will be made of a writing operation in a memory cell of the 1T-DRAM using an SOI-MOSFET with reference to FIGS. 7A and 7B. FIG. 7A illustrates a “1” writing operation, and FIG. 7B illustrates a “0” writing operation. Each memory cell dynamically stores a first potential state in which a floating body (the P-type silicon layer 3) holds a large number of carriers (hereafter, referred to as the data “1”), and a second potential state in which the large number of carriers are discharged and the potential is lower than the first potential (hereafter, referred to as the data “0”).

The data “1” is written by connecting the source region to the source line SL to apply a reference potential (ground potential GND in FIG. 7A) thereto. A positive control voltage is applied to the drain region connected to the bit line BL and to the gate electrode connected to the word line WL. The gate electrode is set to a voltage equal to or higher than a threshold voltage, whereby electrons (represented by a solid circle in the figure) are caused to flow from the source to the drain and impinge the drain. At the same time, impact ionization is caused to occur in the vicinity of the drain junction to inject holes thus generated (represented by open circles in the figure) into the body. The data “1” is written by the holes being stored in the body.

The data “0” is written by connecting the source region to the source line SL to apply the reference potential (ground potential GND) thereto. A positive control voltage is applied to the gate electrode 5 and the body potential is raised by the capacity coupling, so that a forward bias current is caused to flow between the drain region and the body. At the same time, a negative control voltage with respect to the reference voltage is applied to the drain region so that a large forward current is caused to flow between the drain region and the body while holding the source region at the reference potential. As a result, the excessive holes are discharged from the body, and the data “0” is written. The memory cell may be read by any of the reading methods as described in the above-mentioned prior art documents or the like, and the description thereof will be omitted.

The semiconductor memory according to the present invention is designed such that the source region and the drain region in the SOI-MOSFET are asymmetrical, having different impurity concentrations. Specifically, the impurity concentration of the heavy-doped region in the drain region is lower than the impurity concentration of the heavy-doped region in the source region. The drain region having a lower impurity concentration relieves the electric field and suppresses the GIDL leakage. On the other hand, the source region having a higher impurity concentration increases the potential barrier between the body and the source to suppress the leakage of stored charge to between the body and the source region. As a result, the charge holding characteristic of the body which is an opposite conductivity type semiconductor layer interposed between the source region and the drain region can be improved. This improves the data holding characteristic of the memory cell. Thus, a semiconductor memory having a memory cell with excellent data holding characteristic can be obtained.

### Second Exemplary Embodiment

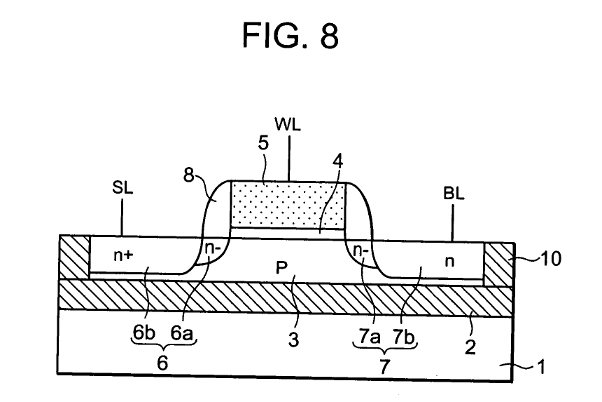

A second exemplary embodiment of a semiconductor memory according to the present invention will be described with reference to FIG. 8. According to the second exemplary embodiment, the high-doped region 6b of the source region and the high-doped region 7b of the drain region are formed such that the high-doped regions are not deep enough to reach the insulating film 2, and a p-n junction is formed in the P-type silicon layer 3.

As shown in FIG. 8, the high-doped regions 6b and 7b of the source region and the drain region of the memory cell are not deep enough to reach the insulating film 2. A p-n junction of the high-doped regions 6b and 7b is formed at a position deeper than the lightly-doped regions 6a and 7a and at an intermediate depth not reaching the insulating film 2. The depth of these high-doped regions can be set by adjusting the ion implantation conditions. Other components of the memory cell of the second exemplary embodiment are the same as those of the first exemplary embodiment and description thereof will be omitted here.

According to the second exemplary embodiment, the high-doped regions 6b and 7b are not deep enough to reach the insulating film 2, which makes it possible to enable the region of the P-type silicon layer 3 to extend not only below the gate electrode layer but also below the source region and the drain region. The expansion of the region of the P-type silicon layer 3 increases the amount of storable charge, giving an extra effect of improving the refresh characteristic. Further, like the first exemplary embodiment, the impurity concentration of the high-doped region in the drain region is made lower than that of the high-doped region in the source region. The drain region having a lower impurity concentration relieves the electric field, and suppresses the GIDL leakage. On the other hand, the source region having a higher impurity concentration increases the potential barrier between the body and the source, which suppresses the leakage of stored charge to between the body and the source region.

According to the present invention, the impurity concentration of the high-doped region in the drain region is made lower than that of the high-doped region in the source region. The GIDL leakage can be suppressed by forming drain region to have a lower impurity concentration. On the other hand, the impurity concentration of the high-doped region in the source region is set relatively high so that the leakage of stored charge to between the body and the source region is suppressed. Further, the body which is the P-type silicon layer is formed as a region extending below the gate electrode and below the diffusion layers, whereby the amount of storable charge can be increased, resulting in improvement of the charge holding characteristic. This improves the data holding characteristic of the memory cell, and a semiconductor memory having a memory cell with excellent data holding characteristic can be obtained.

Although the present invention has been described based on the two exemplary embodiments, the present invention is not limited to these exemplary embodiments. It should be understood that various changes and modifications are possible without departing from the scope of the invention, and all these changes and modifications are also included in the present invention. For example, in the exemplary embodiments described above, the P-type silicon layer 3 in each transistor is surrounded by the element isolation insulating film 10. However, the P-type silicon layers 3 in a plurality of transistors may be surrounded together by the element isolation insulating film 10. It will suffice if the element isolation insulating film 10 is formed at the ends of the P-type silicon layer. Although the description of the exemplary embodiments above has been made in terms of the example of the n-channel MOSFET, a p-channel MOSFET may be used instead.

The present invention is suitably applicable to semiconductor devices utilizing a general-purpose DRAM or integrated DRAM in which a channel of a transistor serves as a memory node.

What is claimed is:

1. A semiconductor memory composed of single-transistor-cell type memory cells, wherein:
a memory cell transistor formed in a semiconductor region on an insulating film includes a drain region, a source region, and a gate electrode;
each of the drain region and the source region has a lightly-doped region and a high-doped region;
the high-doped regions of the drain region and source region are asymmetrical, having different impurity concentrations from each other.

2. The semiconductor memory according to claim 1, wherein the impurity concentration of the high-doped region in the drain region is lower than the impurity concentration of the high-doped region in the source region, and higher than the impurity concentration of the lightly-doped regions in the drain region and the source region.

3. The semiconductor memory according to claim 2, wherein the high-doped regions of the drain region and the source region are formed to be deep enough to reach the insulating film.

4. The semiconductor memory according to claim 2, wherein the high-doped regions of the drain region and the source region are formed to have a depth that is not great enough to reach the insulating film but greater than the depth of the lightly-doped regions of the drain region and the source region.

5. The semiconductor memory according to claim 2, wherein the drain region is connected to a bit line, the source region is connected to a source line, and the gate electrode is connected to a word line, an amount of charge stored in a semiconductor region below the gate electrode being used as stored information.

6. A manufacturing method of a semiconductor memory composed of single-transistor-cell type memory cells, comprising the steps of:
isolating an element region in a semiconductor region on an insulating film by surrounding the element region with an element isolation insulating film;
forming a gate electrode on the semiconductor region with a gate insulating film interposed therebetween;
implanting an impurity in lightly-doped regions of a drain region and a source region in the semiconductor region;
implanting an impurity only in a high-doped region of the source region; and
further implanting an impurity in the high-doped regions of the drain region and the source region.

7. The manufacturing method of a semiconductor memory according to claim 6, wherein in the step of implanting an impurity only in the high-doped region of the source region, the high-doped region of the drain region is covered with a resist, and the impurity is implanted in the high-doped region of the source region by using an ion implantation method.
